(19) United States
(12) Patent Application Publication
(10) Pub. No.: US 2024/0021485 A1
(43) Pub. Date: Jan. 18, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Kuei-Sung Chang, Kaohsiung city (TW); Wen-Tuan Lo, Hsinchu City (TW); Shang-Ying Tsai, Taoyuan City (TW)

(73) Assignee: Taiwan Semiconductor Manufacturing Company, Ltd., Hsinchu (TW)

(21) Appl. No.: 17/862,422

(22) Filed: Jul. 12, 2022

(51) Int. Cl. H01L 21/66; H01L 23/10; H01L 23/055; H01L 21/48

(52) U.S. Cl. CPC H01L 22/12; H01L 22/30; H01L 23/10; H01L 23/055; H01L 21/4817; H01L 24/16

(57) ABSTRACT

A semiconductor package and a manufacturing method thereof are provided. The semiconductor package includes a circuit board, a semiconductor die disposed on the circuit board, a support structure disposed on the circuit board and surrounding the semiconductor die, and a lid disposed over the semiconductor die and on the support structure. The lid has a window opening penetrating through the lid and exposing at least a portion of the semiconductor die. The window opening is configured to receive a light of an incident direction, and the incident direction is at an angle to the upper surface of the protrusion portion, so that the light hitting on the upper surface of the protrusion portion is reflected.

### BACKGROUND

In semiconductor packaging technology, various types of semiconductor dies of different dimensions may be mounted on a circuit board and packaged together. Compact packaging with good reliability is rather challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of a semiconductor package according to some embodiments of the present disclosure.

FIG. 1B is an enlarged schematic 3D cross-sectional view of area 1 A1 in FIG. 1A.

FIGS. 1C through 1E are schematic plan views of FIG. 1A according to some embodiments of the present disclosure.

FIG. 2A is a schematic cross-sectional view of a semiconductor package according to some embodiments of the present disclosure.

FIG. 2B is a schematic plan view of FIG. 2A according to some embodiments of the present disclosure.

FIGS. 3A through 3C are enlarged schematic cross-sectional views of area A2 in FIG. 1B according to some embodiments of the present disclosure.

FIG. 4 is a schematic cross-sectional view of a semiconductor package according to some embodiments of the present disclosure.

FIG. 5 is a schematic cross-sectional view of a semiconductor package according to some embodiments of the present disclosure.

FIG. 6A is a schematic cross-sectional view of a semiconductor package according to some embodiments of the present disclosure.

FIG. 6B is a schematic plan view of FIG. 6A according to some embodiments of the present disclosure.

FIG. 7A through FIG. 7F are schematic cross-sectional views illustrating structures formed at various stages of a manufacturing method of a semiconductor package according to some embodiments of the present disclosure.

FIG. 8A through FIG. 8B are schematic cross-sectional views illustrating structures formed at various stages of a manufacturing method of a lid according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

According to embodiments of the present disclosure, a semiconductor package is described. In some embodiments, the semiconductor package includes a lid disposed over a semiconductor die, and the lid has at least one window opening with a protrusion portion at a bottom portion of the window opening. Through the window opening, a gap between the semiconductor die and the lid could be easily measured by a suitable optical device.

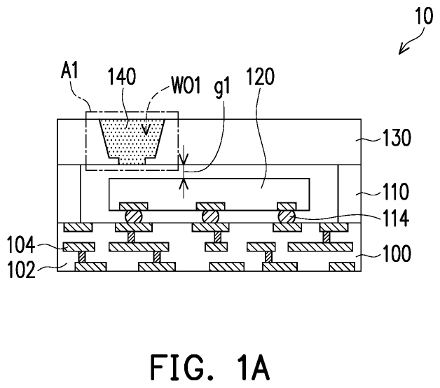

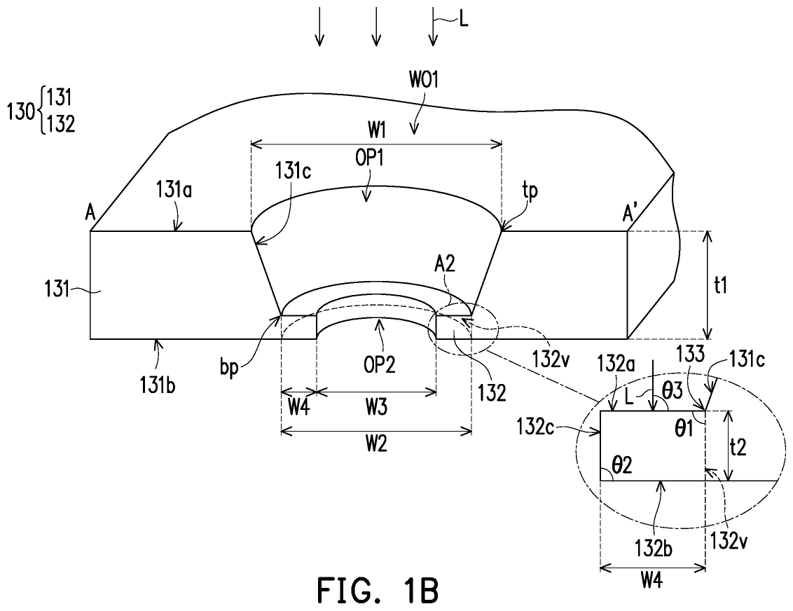

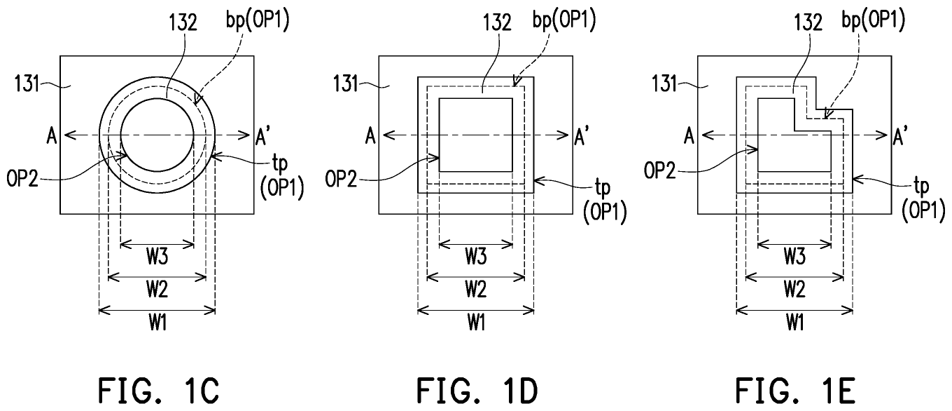

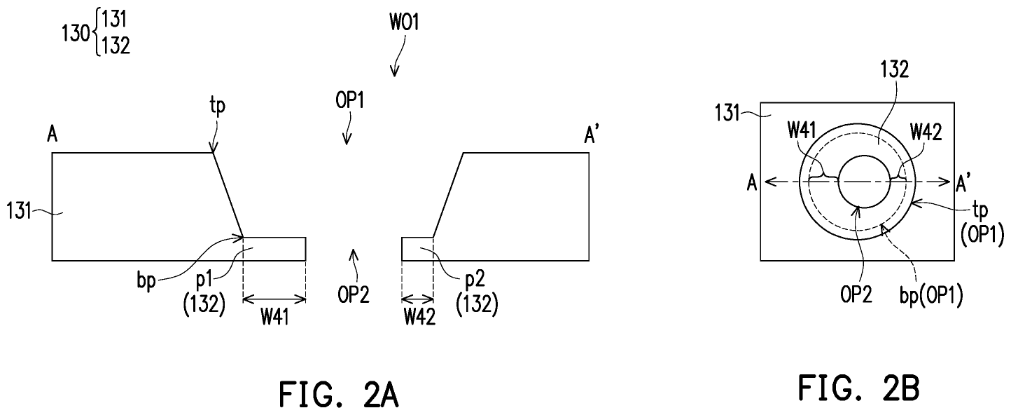

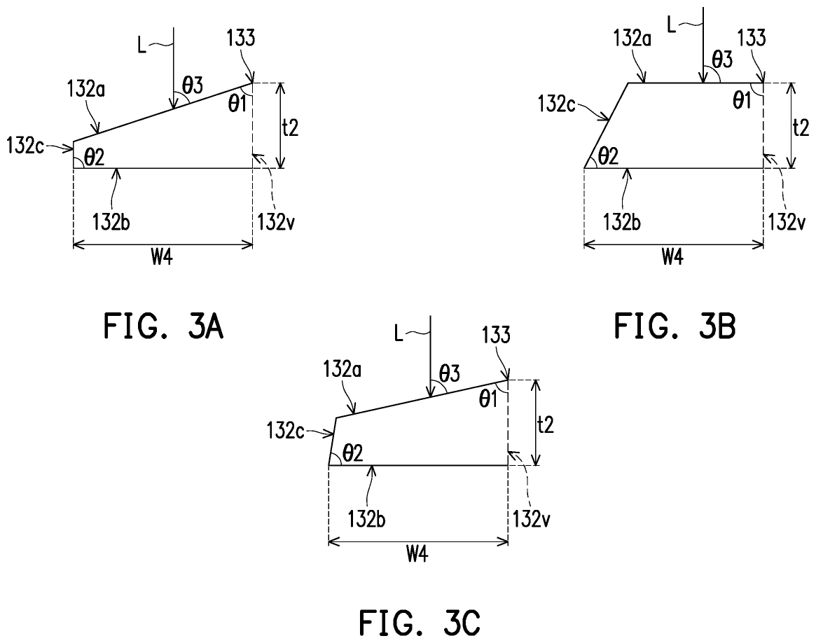

FIG. 1A illustrates a cross-sectional view of a semiconductor package 10 according to some embodiments of the present disclosure. FIG. 1B is an enlarged schematic 3D cross-sectional view of area A1 in FIG. 1A according to some embodiments of the present disclosure. FIGS. 1C through 1E are schematic plan views of FIG. 1A according to some embodiments of the present disclosure. FIG. 2A is an enlarged schematic cross-sectional view of area A1 in FIG. 1A according to some other embodiments of the present disclosure. FIG. 2B is a schematic plan view of FIG. 2A according to some embodiments of the present disclosure. FIGS. 3A through 3C are enlarged schematic cross-sectional views of area A2 in FIG. 1B according to some embodiments of the present disclosure. For clear illustration, the sealant component is omitted in FIGS. 1B-1C, 2A-2C and 3A-3B.

Referring to FIG. 1A, a semiconductor package 10 is described, and the semiconductor package 10 comprises a circuit board 100, a semiconductor die 120 disposed on the circuit board 100, a support structure 110 disposed on the circuit board 100 and around the semiconductor die 120 and a lid 130 disposed over the support structure 110 and covering the semiconductor die 120. In some embodiments, the circuit board 100 may include a plurality of insulating layers 102 and a plurality of wiring layers 104 stacked in alternation. In some embodiments, the circuit board 100 may be or include a printed circuit board (PCB), a flexible printed circuit (FPC) or the like, and the circuit board 100 establish electrical connection between the semiconductor die 120 and the outside environment.

In some embodiments, the semiconductor die 120 is disposed on the circuit board 100 and electrically connected to the circuit board 100 through the connectors 114. In some embodiments, the semiconductor die 120 may include a logic die, a memory die or a semiconductor die including one or more devices and/or components such as transistors, diodes, MEMS devices, passive devices (such as resistors, capacitors, inductors and the like), sensors (such as image sensors, motion sensors, microphones and the like), actuators (such as speakers, motion stabilizers and the like) or the like. In some embodiments, the connectors 114 include gold bumps, micro-bumps, metal posts, ball grid array (BGA) bumps, C4 bumps or solder bumps. In some embodiments, the connectors 114 might use wire bonding instead of bumps. One end of the wire is bonded at one side of the semiconductor die 120, and the other end of the wire is bonded at one side of the wiring layers 104 of circuit board 100.

In some embodiments, the support structure 110 is disposed on the circuit board 100 and surrounds the semiconductor die 120. In some embodiments, the material of the support structure 110 includes epoxy resins, ceramics or other suitable materials.

In some embodiments, the lid 130 is disposed over the semiconductor die 120 and on the support structure 110. There is a gap g1 between the lid 130 and the semiconductor die 120. In some embodiments, the lid 130 has a first window opening WO1 penetrating through the lid 130 and exposing at least a portion of the semiconductor die 120. That is, the location of the first window opening WO1 is overlapped with the location of the semiconductor die 120 so that at least a portion of the semiconductor die 120 is exposed by the first window opening WO1. In some embodiments, the material of the lid 130 includes epoxy resins, ceramics or other suitable materials. In some embodiments, the material of the lid 130 and the material of the support substrate 110 are the same. In other embodiments, the material of the lid 130 may be different from the material of the support substrate 110.

Referring to FIG. 1B and FIG. 1C, the lid 130 comprises a body portion 131 and a protrusion portion 132 connected with the body portion 131. In some embodiments, the lid 130 has a first window opening WO1 defined by the body portion 131 and the protrusion portion 132. As seen in FIG. 1B, the protrusion portion 132 protrudes inwardly from the lower part of the body portion 131. As seen in FIG. 1B, the body portion 131 has a top surface 131a, a bottom surface 131b facing the semiconductor die 120 and opposite to the top surface 131a, and an inner sidewall 131c connected to the top surface 131a. In some embodiments, the first opening OP1 is defined by the inner sidewall 131c of the body portion 131. As seen in FIG. 1B, the protrusion portion 132 has an upper surface 132a, a bottom surface 132b facing the semiconductor die 120 and coplanar with the bottom surface 131b, and a sidewall 132c connected with the upper surface 132a and the bottom surface 132b. In some embodiments, the upper surface 132a of the protrusion portion 132 is connected to the inner sidewall 131c of the body portion 131.

As seen in FIG. 1B, the inner sidewall 131c is a slant sidewall, the first opening OP1 has a top width W1 at a top portion tp of the first opening OP1, and a lower width W2 at a lower portion bp of the first opening OP1. In some embodiments, the top width W1 is larger than the lower width W2. In other words, the upper portion of the first opening OP1 is wider than the lower portion of the first opening OP1 and there is an obtuse angle between the inner sidewall 131c and the upper surface 132a of the protrusion portion. In some embodiments, the inner sidewall 131c may be slightly tilted or sloped but not perpendicular to the surface 131a or 131b.

In some embodiments, a ratio of the lower width W2 to the top width W1 may be between 0.4 to 1. In some embodiments, the top width W1 may be in a range of 50 μm to 1000 μm, and the lower width W2 may be in a range of 20 μm to 1000 μm. In some embodiments, the body portion 131 may have a uniform thickness t1, and the thickness t1 may be in a range of 50 μm to 500 μm. The ratio, the width W1, W2 and the thickness t1 may be adjusted according to the actual requirements of the product.

In some embodiments, measuring from the virtual normal plane 132v (plane normal/vertical to the surface 131b/132b) cutting through the intersection 133 of the inner sidewall 131c of the body portion 131 and the upper surface 132a of the protrusion portion 132, the protrusion portion 132 is protruded from the body portion 131 with an extended distance W4. As seen in FIG. 1B, the bottom surface 132b of the protrusion portion 132 and the bottom surface 131b of the body portion 131 are coplanar and the same surface. In some embodiments, in FIG. 1B, the second opening OP2 is defined by the first sidewall 132c of the protrusion portion 132. In some embodiments, the sidewall 132c is substantially vertical to the bottom surface 132b, and the second opening OP2 has a uniform width W3. The second opening OP2 is joined with the first opening OP1 to form the first window opening WO1. As seen in FIG. 1B, the width W3 of the second opening OP2 is smaller than the minimum width W2 of the first opening OP1, and the difference between the widths W3 and W2 (i.e. W2-W3) accounts for two times of the extended distance W4. In some embodiments, the width W3 of the second opening OP2 may be in a range of 10 μm to 980 μm. In some embodiments, a ratio of the width W3 of the second opening OP2 to the lower width W2 of the first opening OP2 is between 0.5 and 0.98. The ratio and the width W3 may be adjusted according to the actual requirements of the product.

In some embodiments, the first window opening WO1 includes the first opening OP1 defined by the inner sidewall 131c of the body portion 131 and the second opening OP2 defined by the inner sidewall 132c of the protrusion portion 132. In embodiments, the first window opening WO1 is configured to receive the incident light L, and the light L passing through the first window opening WO1 may be reflected by the upper surface 132a or by the top surface of the semiconductor die 120. By doing so, the dimension of the gap g1 existing between the bottom surface of the lid 130 and the top surface of the semiconductor die 120 can be measured. In some embodiments, the first window opening WO1 is formed with suitable surface profiles so that the light L is significantly reflected or fully reflected by the surface 132a of the protrusion portion 132. That is, the surface 132a of the protrusion portion 132 functions as a reference plane, and the incident light L is reflected back by such reference plane (surface) with the largest intensity and detected by an optical device.

In some embodiments, relative to the top surface of the semiconductor die 120, the upper surface 132a of the protrusion portion 132 is substantially parallel to the surface of the semiconductor die 120 and is at an angle or is substantially perpendicular to the incidence direction of the light L. Since the protrusion portion 132 protrudes inwardly toward the middle of the first window opening WO1, the upper surface 132a of the protrusion portion 132 can better reflect the incident light than the inner sidewall 131c, so that a higher intensity of the light reflection is obtained via the upper surface 132a of the protrusion portion 132, and more precise and better measurement of the gap g1 is achieved.

In some embodiments, the protrusion portion 132 may have a uniform thickness t2 and/or a uniform extended distance or width W4. The thickness t2 of the protrusion portion 132 is measured between the upper surface 132a and the bottom surface 132b. For example, in the present embodiment shown in FIG. 1B, the upper surface 132a and the bottom surface 132b are parallel as well as the sidewall 132c is substantially perpendicular to the upper surface 132a and the bottom surface 132b. Therefore, an angle θ1 between the upper surface 132a and the virtual normal plane 132v is about 90 degrees and an angle θ2 between the sidewall 132c and the bottom surface 132b is about 90 degrees. In FIG. 1B, in some embodiments, considering the incident direction of the light L (shown as arrows) is substantially normal to the upper surface 132a, the light L hitting on the upper surface 132a is at the angle θ3 of about 90 degrees. In one embodiment, the angle of about 90 degrees refers to the angle of 89-91 degrees or 90±1 degrees.

However, the protrusion portion 132 is not limited to the configurations depicted in the above embodiment. FIGS. 3A through 3C are enlarged schematic cross-sectional views of area A2 in FIG. 1B according to some embodiments of the present disclosure, and show some other exemplary configurations of the protrusion portion 132.

In some embodiments, the thickness t2 may vary with the inclination of the upper surface 132a, and/or the width W4 may vary with the inclination of the sidewall 132c. For example, shown in FIG. 3A, the upper surface 132a may be slant and the sidewall 132c may be substantially parallel to the virtual normal plane 132v perpendicular to the bottom surface 132b. That is, the cross section of the protrusion portion 132 may be a trapezoid shape. The angle θ1 between the upper surface 132a and the virtual normal plane 132v may be an acute angle. For example, the angle θ1 may be larger than 45 degrees and smaller than 90 degrees. The angle θ2 between the first sidewall 132c and the bottom surface 132b may be about 90 degrees. That is to say, the thickness t2 of the protrusion portion 132 may vary due to a slope of the upper surface 132a, and the width W4 of the protrusion portion 132 may be uniform. In some embodiments, the incident direction of the light L (shown as arrows) is at the angle θ3 to the upper surface 132a, and the angle θ3 may be the same as the angle θ1 between the upper surface 132a and the virtual normal plane 132v. In other words, the angle θ3 may be an acute angle.

In some embodiments, as shown in FIG. 3B, the upper surface 132a and the bottom surface 132b are parallel as well as the sidewall 132c may be slant. For example, the angle θ1 between the upper surface 132a and the virtual normal plane 132v may be around 90 degrees and the angle θ2 between the sidewall 132c and the bottom surface 132b may be smaller than 90 degrees. In some embodiments, the angle θ2 may be between 10 degrees to 90 degrees. The width W4 of the protrusion portion 132 may decrease away from the bottom surface 132b of the protrusion portion 132, and correspondingly, the width W3 (labeled in FIG. 1B) of the second opening OP2 may increase away from the bottom surface 132b of the protrusion portion 132, but the maximum width W3 of the second opening OP2 is smaller than the minimum width W2 (labeled in FIG. 1B) of the first opening OP1. In some embodiments, the incident direction of the light L (shown as arrows) is substantially normal to the upper surface 132a, that is, the angle θ3 may be a right angle.

In some embodiments, as shown in FIG. 3C, both the upper surface 132a and the first sidewall 132c may be slant. For example, the angle θ1 may be between 45 degrees to 90 degrees and the angle θ2 may be between 10 degrees to 90 degrees. That is to say, both the thickness t2 and the width W4 may vary with the inclination of the upper surface 132a and the sidewall 132c. It is appreciated that the angle θ1 between the upper surface 132a and the virtual normal plane 132v and the angle θ2 between the sidewall 132c and the bottom surface 132b are not limited, and they can be adjusted according to the actual requirement.

In some embodiments, the thickness t1 of the body portion 131 is larger than the thickness t2 of the protrusion portion 132. In some embodiments, a ratio of the maximum thickness t2 of the protrusion portion 132 to the thickness t1 of the body portion 131 is between 0.1 and 0.8, but not limited. Here, the maximum thickness t2 of the protrusion portion 132 is the distance from the intersection 133 of the inner sidewall 131c and the upper surface 132a to the bottom surface 132b. In some embodiments, the maximum thickness t2 of the protrusion portion 132 may be between 5 μm to 400 μm, but not limited. The thinner the protrusion portion 132, the less influence for the accuracy of the measurement of the gap g1 is, since the tolerance of the protrusion portion 132 can be smaller.

In some embodiments, from the top view of area A1, a shape of the top portion tp of the first opening OP1, a shape of the lower portion bp of the first opening OP1 and a shape of the second opening OP2 are similar, but not limited. For example, as shown in FIG. 1C, the shape of the top portion tp of the first opening OP1, the shape of the lower portion bp of the first opening OP1 and the shape of the second opening OP2 are circular, but not limited. In other embodiments, as shown in FIGS. 1D and 1E, the shape of the top portion tp of the first opening OP1, the shape of the lower portion bp of the first opening OP1 and the shape of the second opening OP2 from the top view may be rectangle or L-like shape. Although FIGS. 1C to 1E illustrates three kinds of the shape for the top portion tp of the first opening OP1, the shape of lower portion bp of the first opening OP1 and the second opening OP2, it is appreciated that the shape of the top portion tp of the first opening OP1, the shape of the lower portion bp of the first opening OP1 and the shape of the second opening OP2 from the top view may be some other kinds of shape, such as oval, polygon or the like, and may be adjustable according to the actual requirement.

In some embodiments, referring to FIGS. 1B to 1E, the shape of the top portion tp of the first opening OP1, the shape of the lower portion bp of the first opening OP1 and the shape of the second opening OP2 have the same geometric center. Therefore, the width W4 between the first sidewall 132c to the virtual normal plane 132v is the same everywhere for the protrusion portion 132. For example, the widths W4 of the protrusion portion 132 at the opposite sides of the second opening OP2 may be the same. In some embodiments, the first opening OP1 and the second opening OP2 are concentric as shown in FIGS. 1C and 1D.

In some embodiments, the width W4 of the protrusion portion 132 is not uniform throughout. Referring to FIGS. 2A and 2B, the first opening OP1 and the second opening OP2 are eccentric, so that the widths W4 of the protrusion portion 132 at the opposite sides of the second opening OP2 may be the different. For example, the protrusion portion 132 may comprise a first part p1 and a second part p2 at the opposite sides of the second opening OP2, respectively. The width W41 of the first part p1 is larger than the width W42 of the second part p2, since the position of the center of the second opening OP2 is different form the position of the center of the lower portion bp of the first opening OP1.

Referring to FIG. 1A, a sealant component 140 is filled in the first window opening WO1. The material of the sealant component 140 may be polymer (such as epoxy resins, silicone or the like), glass frit or other suitable materials. The sealant component 140 can prevent contamination of the semiconductor die 120 due to moisture or dust. In some embodiments, the sealant component may be transparent or opaque.

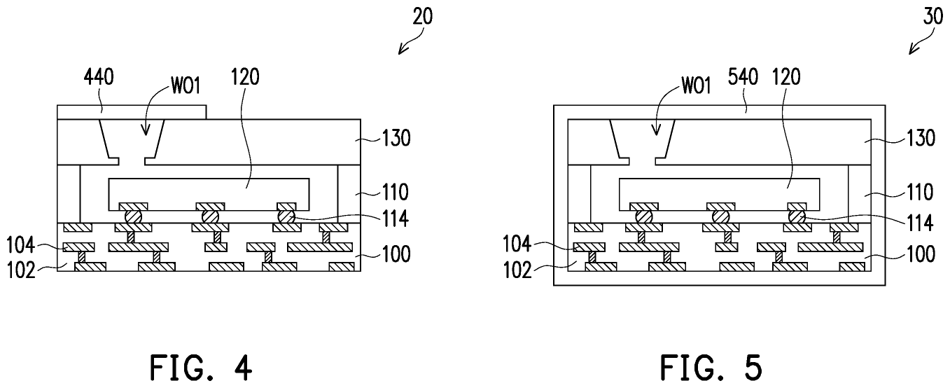

FIG. 4 is a schematic cross-sectional view of a semiconductor package 20 according to some embodiments of the present disclosure. It should be noted herein that, in embodiments provided in FIG. 4, element numerals and partial content of the embodiments provided in FIG. 1A are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 4, the difference between the present embodiment to the semiconductor package 10 is that the semiconductor package 20 comprises a sealant component 440, and the sealant component 440 is disposed on a surface of the lid 130 away from the support structure 110 and above the window opening WO1. The material of the sealant component 440 may be plastic, glass, metal, ceramics or other suitable materials. In some embodiments, the sealant component 440 may be plate-shaped and an area of the sealant component 440 is larger than the area of the top portion tp of the first window opening WO1 to fully cover the first window opening WO1.

In some embodiments, the sealant component 440 may be attached to the lid 130 by a sealant (not shown).

In some embodiments, an additional sealant component (not shown) similar to the sealant component 140 in FIG. 1A may be filled within the first window opening WO1. In other words, the first window opening WO1 may be filled by the additional sealant component and covered by the sealant component 440.

FIG. 5 is a schematic cross-sectional view of a semiconductor package 30 according to some embodiments of the present disclosure. It should be noted herein that, in embodiments provided in FIG. 5, element numerals and partial content of the embodiments provided in FIG. 1A are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 5, the difference between the present embodiment to the semiconductor package 10 is that the semiconductor package 30 comprises a sealant component 540. The sealant component 540 may be a cover, a case, a frame or the like, so that the circuit board 100, the support structure 110, the semiconductor die 120 and the lid are disposed inside the sealant component 540 for isolation and protection. The material of the sealant component 540 may be plastic, glass, metal, ceramics or other suitable materials.

In some embodiments, the first window opening WO1 may be filled by an additional sealant component (not shown) similar to the sealant component 140 in FIG. 1A.

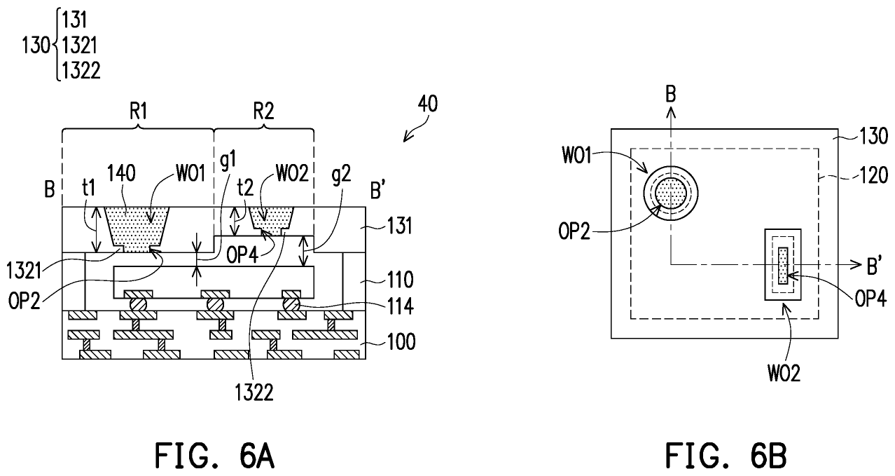

FIG. 6A is a schematic cross-sectional view of a semiconductor package 40 according to some embodiments of the present disclosure. FIG. 6B is a schematic plan view of FIG. 6A according to some embodiments of the present disclosure. It should be noted herein that, in embodiments provided in FIGS. 6A and 6B, element numerals and partial content of the embodiments provided in FIG. 1A are followed, the same or similar reference numerals being used to represent the same or similar elements, and description of the same technical content being omitted. For a description of an omitted part, reference may be made to the foregoing embodiment, and the descriptions thereof are omitted herein. For clear illustration, the support structure is omitted in FIG. 6B.

Referring to FIGS. 6A and 6B, the difference between the semiconductor package 40 in FIG. 6A and the semiconductor package 10 in FIG. 1A is that the lid 130 has a first window opening WO1 in a first region R1 and a second window opening WO2 in a second region R2. The lid 130 has a first thickness t1 in the first region R1 and a second thickness t2 in the second region R2 that is different from the first thickness t1. In some embodiments, a gap g1 between the first region R1 and the semiconductor die 120 is different from a gap g2 between the second region R2 and the semiconductor die 120. The lid 130 comprises a body portion 131, a first protrusion portion 1321 located at a lower portion of the first window opening WO1 and a second protrusion portion 1322 located at a lower portion of the second window opening WO2. The first and second window openings WO1, WO2 are configured to receive a light of an incident direction, the incident direction is at a first angle to a first light receiving surface of the first protrusion portion 1321 and at a second angle to a second light receiving surface of the second protrusion portion 1322, so that the light hitting on the first light receiving surface or the second light receiving surface is reflected. The first window opening WO1 in the present embodiment may be similar to the window opening WO1 in the aforementioned embodiments, while the second window opening WO2 may have different dimensions and profiles. The first protrusion portion 1321 and the second protrusion portion 1322 in the present embodiment may be similar to the first protrusion portion 132 in the aforementioned embodiments. For example, the first angle and the second angle may be similar to the angle θ3 in the aforementioned embodiments. The first light receiving surface can be an upper surface of the first protrusion portion 1321 and the second light receiving surface can be an upper surface of the second protrusion portion 1322.

In some embodiments, a dimension of the first window opening WO1 and a dimension of the second window opening WO2 may be different or the same, which is not limited. In some embodiments, a dimension of the first protrusion portion 1321 and a dimension of the second protrusion portion 1322 may be different or the same, which is not limited. For example, the first window opening WO1 and the second window opening WO2 may have different maximum widths.

In one embodiment, as seen in FIG. 6B, the projection of the lower opening OP2 of the window opening WO1 is overlapped with and falls within the span of the semiconductor die 120, and the projection of the lower opening OP4 of the window opening WO2 is overlapped with and falls within the span of the semiconductor die 120.

In some embodiments, a shape of the first window opening WO1 and a shape of the second window opening WO2 may be circular, oval, rectangular, polygon-shaped, L-shaped or the like, which is not limited. In some embodiments, a shape of the first window opening WO1 and a shape of the second window opening WO2 from the top view may be different. For example, as shown in FIG. 6B, the lower opening OP2 of the first window opening WO1 is in circular shape and the lower opening OP4 of the second window opening WO2 is in rectangular shape. In other embodiments, the shape of the first window opening WO1 and the shape of the second window opening WO2 from the top view may be the same.

Although FIGS. 6A and 6B illustrates two window openings, it is appreciated that the number of window openings is not limited and may be adjustable according to the actual requirement.

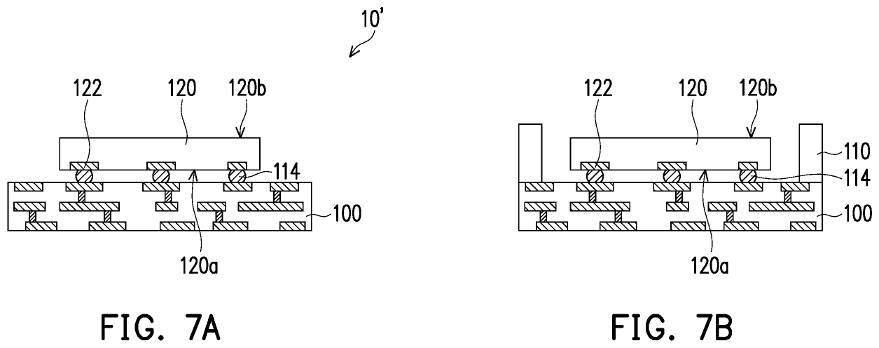

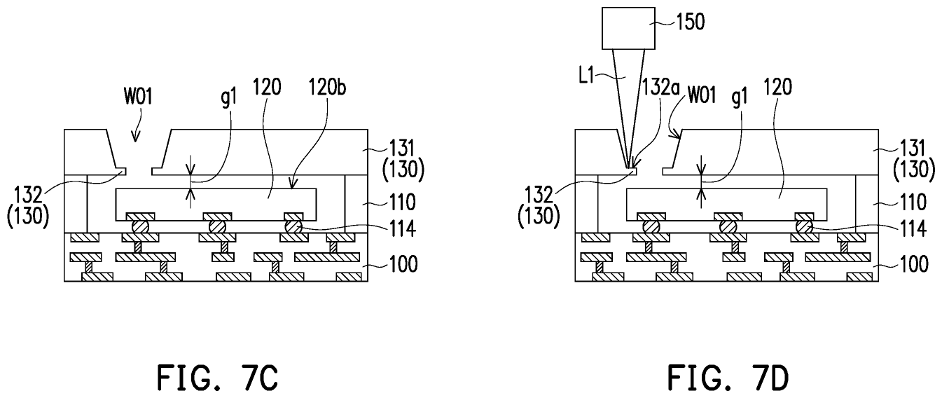

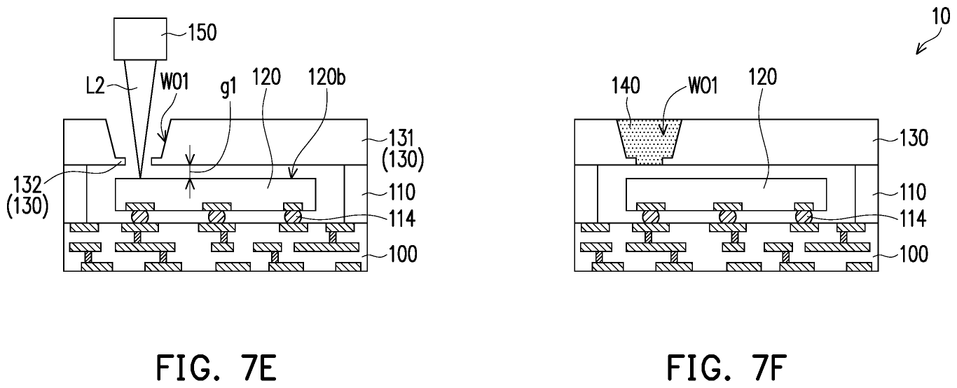

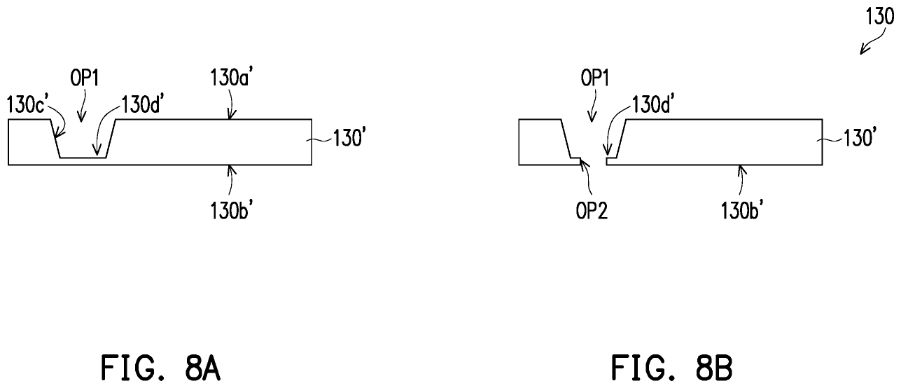

FIG. 7A through FIG. 7F are schematic cross-sectional views illustrating structures formed at various stages of a method according to some embodiments of the present disclosure. The method involves the manufacture and the measurement of the semiconductor die 10. FIG. 8A through FIG. 8B are schematic cross-sectional views illustrating structures formed at various stages of a manufacturing method of a lid 130 according to some embodiments of the present disclosure. It should be noted herein that, in embodiments provided in FIGS. 7A to 7F and 8A to 8B, element numerals and partial content of the embodiments provided in FIG. 1A are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 7A, a semiconductor package 10′ having a semiconductor die 120 disposed on a circuit board 100 is provided. The semiconductor die 120 has an active surface 120a and a back surface 120b. The active surface 120a may include active components (not shown) and contacts 122 to electrically connect to the outside. In the present embodiment, the active surface 120a of the semiconductor die 120 faces to the circuit board 100, and the semiconductor die 120 may be bonded to the circuit board 100 though flip chip technologies using the connectors 114 such as metal pillars, controlled collapse chip connection (C4) bumps, micro bumps or combinations thereof.

Although FIG. 7A illustrates the flip-chip bonding, it is not limited. In other embodiments, the semiconductor die 120 may be bonded to the circuit board 100 by wire bonding. For example, the back surface 120b of the semiconductor die 120 may be attached to the circuit board 100 by a die attach film. That is, the back surface 120b may face the circuit board 100 in this embodiment. The contacts 122 of the semiconductor die 120 are electrically connected to the corresponding circuit of the circuit board 100 through wire bonding.

Referring to FIG. 7B, a support structure 110 is disposed on the circuit board 100 and surrounds the semiconductor die 120. In some embodiments, the support structure 110 may be attached to the circuit board 100 by a sealant (not shown). The material of the circuit board 100 and the support structure 110 in FIG. 7A may be similar to the circuit board 100 and the support structure 110 in FIG. 1A.

Referring to FIG. 7C, a lid 130 is disposed on the support structure 110 and over the semiconductor die 120 with a gap g1 between the lid 130 as well as the semiconductor die 120. For example, the lid 130 is prefabricated and attached to the support structure 110 by a sealant (not shown). In some embodiments, the lid 130 may be fabricated by molding directly. The lid 130 has a window opening WO1 penetrating through the lid 130 and exposing at least a portion of the semiconductor die 120. The lid 130 includes a body portion 131 and a protrusion portion 132 connected with the body portion 131 and protruded from the body portion 131 and the window opening WO1 is configured to receive a light. In some embodiment, the support structure 110 and the lid 130 may be fabricated together by mold injection with the same body. That is, the support structure 110 and the lid 130 may be disposed over the circuit board 100 at once.

In other embodiments, the lid 130 may be fabricated by the following steps as shown in FIGS. 8A to 8B. Referring to FIG. 8A, a main body 130′ is fabricated by molding, and the main body has a first surface 130a′, a second surface 130b′ opposite to the first surface 130a′, a sidewall 130c′ connected with the first surface 130a′ and a bottom surface 130d′ connected with the sidewall 130c′. A first opening OP1 is defined by the sidewall 130c′ and does not penetrate through the main body 130′. In some embodiments, the sidewall 130c′ may be slant, so that a width at a top portion of the first opening OP1 (that is, the width of the first opening OP1 near the first surface 130a′) is larger than a width at a bottom portion of the first opening OP1 (that is, the width of the first opening OP1 near the bottom surface 130d′). In other embodiments, the sidewall 130c′ may be perpendicular to the first surface 130a′, so that the width of the first opening OP1 may be uniform.

Then, referring to FIG. 8B, a second opening OP2 is formed and penetrates from the second surface 130b′ of the main body 130′ to the bottom surface 130d′ of the first opening OP1, and therefore the first opening OP1 and the second opening OP2 are connected to form the first window opening WO1. In some embodiments, the second opening OP2 may be formed by mechanical drilling, laser drilling, punching or the like. A width of the second opening OP2 is smaller than the width at a bottom portion of the first opening OP1. In some embodiments, the first opening OP1 and the second opening OP2 may be concentric or eccentric. Based on the above, the fabrication of the lid 130 is substantially completed.

Referring to FIG. 7D, a distance of the gap g1 between the lid 130 and the semiconductor die 120 may be measured through the first window opening WO1 by an optical device. For example, the optical device 150 may comprise a light source and an optical sensor to transform a light signal to an electronic signal. In some embodiments, the light source may emit a visible light, but not limited. In some embodiments, the light source may be configured to emit an invisible light, such as an X-ray, IR (infrared), UV (ultraviolet) or the like. The optical sensor may be a CMOS (complementary metal oxide semiconductor) image sensor (CIS), a charge-coupled device (CCD) or the like, to sense the light reflected from the object to be measured. In some embodiments, the position of the optical device 140 may be adjustable by a motor (not shown) to align with the first window opening WO1 of the lid 130. In some embodiments, the optical device may be for example, a digital optical microscope, a CCD camera, an interferometer or the like.

In detail, the distance of the gap g1 between the lid 130 and the semiconductor die 120 may be measured by the following steps. A first light L1 of a first incident direction is emitted to the semiconductor package 10′. The protrusion portion 132 has a light receiving surface (for example, an upper surface 132a of the protrusion portion 132) where the incident first light L1 hits on the light receiving surface and the first incident direction is at an angle to the light receiving surface of the protrusion portion 132. The first light L1 is reflected by the light receiving surface of the protrusion portion 132 passing through the window opening WO1 and detecting the reflected first light from the protrusion portion 132 to obtain a reference plane. In some embodiments, the angle is about 90 degrees. Since the lid 130 has the protrusion portion 132 located at the lower portion of the window opening WO1 and is substantially perpendicular to the first incident direction of the incident light L1, the light L1 can be significantly reflected or fully reflected by the light receiving surface of the protrusion portion 132 with the largest intensity and detected by the optical device 150, so that the reference plane may be clearly detected.

Referring to FIG. 7E, similarly, a second light L2 is emitted to a surface of the semiconductor die 120 (for example, the back surface 120b) through the window opening WO1, and then part of the second light L2 is reflected back to the optical device 150, to obtain a target plane. In some embodiments, the surface of the semiconductor die 120 may be substantially perpendicular to the second light L2, the light L2 can be significantly reflected or fully reflected by the top surface of the semiconductor die 120 with the largest intensity and detected by the optical device 150, so that the target plane may be clearly detected.

Then, the distance of the gap g1 may be measured based on a thickness of the protrusion portion 132 and a distance between the reference plane and the target plane. Through the aforementioned measuring method, the distance of the gap g1 between the lid 130 and the semiconductor die 120 may be derived by the common optical device in a simple way, and is more accurate and with a smaller tolerance compared with the distance of the gap calculating from the dimension of the lid 130, the support structure 110 and the semiconductor die 120, which may contain the tolerances of the lid 130, the support structure 110 and the semiconductor die 120.

Referring to FIG. 7F, after measuring the gap g1 through the first window opening WO1, a sealant component 140 is filled in the first window opening WO1. The material of the sealant component 140 may be similar to the sealant component 140 in FIG. 1A. In other embodiments, the sealant component 140 may be a cover plate similar to the sealant component 440 shown in FIG. 4 or a cover case similar to the sealant component 540 shown in FIG. 5, which is not limited.

According to some embodiments of the present disclosure, a semiconductor package is provided. The semiconductor package includes a circuit board, a semiconductor die disposed on the circuit board, a support structure disposed on the circuit board and surrounding the semiconductor die, and a lid disposed over the semiconductor die and on the support structure. The lid has a window opening penetrating through the lid and exposing at least a portion of the semiconductor die. The lid includes a body portion and a protrusion portion connected with the body portion and protruded from the body portion. The protrusion portion has an upper surface, a bottom surface opposite to the upper surface and a first sidewall connecting the upper surface and the bottom surface. The body portion has a top surface and an inner sidewall connecting the top surface and the upper surface of the protrusion portion. The first window opening is configured to receive a light of an incident direction, and the incident direction is at an angle to the upper surface of the protrusion portion, so that the light hitting on the upper surface of the protrusion portion is reflected.

According to some embodiments of the present disclosure, a semiconductor package is provided. The semiconductor package includes a circuit board, a semiconductor die disposed on the circuit board, a support structure disposed on the circuit board and surrounding the semiconductor die, and a lid disposed over the semiconductor die and on the support structure. The lid has a first window opening in a first region and a second window opening in a second region, and the lid has a first thickness in the first region and a second thickness in the second region that is different from the first thickness. The lid includes a body portion, a first protrusion portion located at a lower portion of the first window opening and a second protrusion portion located at a lower portion of the second window opening. The first and second window openings are configured to receive a light of an incident direction, the incident direction is at a first angle to a first light receiving surface of the first protrusion portion and at a second angle to a second light receiving surface of the second protrusion portion, so that the light hitting on the first light receiving surface or the second light receiving surface is reflected.

According to some embodiments of the present disclosure, a manufacturing method is provided. The manufacturing method includes the following steps. A semiconductor package having a semiconductor die disposed on a circuit board is provided. A support structure is disposed on the circuit board and surrounding the semiconductor die. A lid is disposed over the semiconductor die and on the support structure. The lid has a window opening penetrating through the lid and exposing at least a portion of the semiconductor die. The lid includes a body portion and a protrusion portion connected with the body portion and protruded from the body portion and the window opening is configured to receive a light. A first light of a first incident direction is emitter to the semiconductor package. The protrusion portion has a light receiving surface where the incident first light hits on the light receiving surface and the first incident direction is at an angle to the light receiving surface of the protrusion portion. The first light is reflected by the light receiving surface of the protrusion portion passing through the window opening and detecting the reflected first light from the protrusion portion to obtain a reference plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a circuit board;
a semiconductor die disposed on the circuit board;
a support structure disposed on the circuit board and surrounding the semiconductor die; and
a lid disposed over the semiconductor die and on the support structure, wherein the lid has a window opening penetrating through the lid and exposing at least a portion of the semiconductor die, wherein the lid comprises a body portion and a protrusion portion connected with the body portion and protruded from the body portion, the protrusion portion has an upper surface, a bottom surface opposite to the upper surface and an first sidewall connecting the upper surface and the bottom surface, and the body portion has a top surface and an inner sidewall connecting the top surface and the upper surface of the protrusion portion, and
wherein the window opening is configured to receive a light of an incident direction, and the incident direction is at an angle to the upper surface of the protrusion portion, so that the light hitting on the upper surface of the protrusion portion is reflected.

2. The semiconductor package according to claim 1, wherein the inner sidewall of the body portion is a slant sidewall and there is an obtuse angle between the inner sidewall and the upper surface of the protrusion portion.

3. The semiconductor package according to claim 1, wherein the angle is a right angle.

4. The semiconductor package according to claim 1, wherein the angle is an acute angle.

5. The semiconductor package according to claim 1, wherein the window opening includes a first opening defined by the inner sidewall of the body portion and a second opening defined by the first sidewall of the protrusion portion, a maximum width of the second opening is smaller than a maximum width of the first opening.

6. The semiconductor package according to claim 5, wherein a minimum width of the first opening is larger than the maximum width of the second opening.

7. The semiconductor package according to claim 5, wherein the first opening and the second opening are concentric from a top view.

8. The semiconductor package according to claim 5, wherein the first opening and the second opening are eccentric from a top view.

9. The semiconductor package according to claim 1, further comprising a sealant component disposed inside the window opening.

10. The semiconductor package according to claim 1, further comprising a sealant component disposed on a surface of the lid away from the support structure and above the window opening.

11. A semiconductor package, comprising:
a circuit board;
a semiconductor die disposed on the circuit board;
a support structure disposed on the circuit board and surrounding the semiconductor die; and
a lid disposed over the semiconductor die and on the support structure, wherein the lid has a first window opening in a first region and a second window opening in a second region, and the lid has a first thickness in the first region and a second thickness in the second region that is different from the first thickness,
wherein the lid comprises a body portion, a first protrusion portion located at a lower portion of the first window opening and a second protrusion portion located at a lower portion of the second window opening, and
wherein the first and second window openings are configured to receive a light of an incident direction, the incident direction is at a first angle to a first light receiving surface of the first protrusion portion and at a second angle to a second light receiving surface of the second protrusion portion, so that the light hitting on the first light receiving surface or the second light receiving surface is reflected.

12. The semiconductor package according to claim 11, wherein the first window opening or the second window opening has a round shape, an oval shape, a rectangular shape, an L-like shape or a polygonal shape from a top view.

13. The semiconductor package according to claim 11, wherein the first window opening and the second window opening have different maximum widths.

14. The semiconductor package according to claim 11, wherein a gap between the first region of the lid and the semiconductor die is different from a gap between the second region of the lid and the semiconductor die.

15. The semiconductor package according to claim 11, wherein the first angle is a right angle and the second angle is an acute angle.

16. The semiconductor package according to claim 11, wherein the first angle is about 90 degrees and the second angle is about 90 degrees.

17. The semiconductor package according to claim 11, wherein the first angle is larger than 45 degrees and smaller than 90 degrees and the second angle is about 90 degrees.

18. A manufacturing method, comprising:
providing a semiconductor package having a semiconductor die disposed on a circuit board;
disposing a support structure on the circuit board and surrounding the semiconductor die;
disposing a lid over the semiconductor die and on the support structure, wherein the lid has a window opening penetrating through the lid and exposing at least a portion of the semiconductor die, the lid includes a body portion and a protrusion portion connected with the body portion and protruded from the body portion and the window opening is configured to receive a light;
emitting a first light of a first incident direction to the semiconductor package, wherein the protrusion portion has a light receiving surface where the incident first light hits on the light receiving surface and the first incident direction is at an angle to the light receiving surface of the protrusion portion; and
reflecting the first light by the light receiving surface of the protrusion portion passing through the window opening and detecting the reflected first light from the protrusion portion to obtain a reference plane.

19. The manufacturing method according to claim 18, further comprising
emitting a second light to a surface of the semiconductor die through the window opening;
detecting the reflected second light from the surface of the semiconductor die to obtain a target plane;
measuring a gap distance between the lid and the surface of the semiconductor die based on a thickness of the protrusion portion, the reference plane and the target plane.

20. The manufacturing method according to claim 18, wherein the angle is about 90 degrees.
